(19) United States
(12) Patent Application Publication
(10) Pub. No.: US 2012/0044101 A1
(43) Pub. Date: Feb. 23, 2012

(54) Method for an enhanced incremental-absolute position sensor system

(76) Inventors: John P. Taylor, San Diego, CA (US); Nicholas L. Taylor, Pine Valley, CA (US)

(21) Appl. No.: 12/806,826

(22) Filed: Aug. 23, 2010

(51) Int. Cl. H03M 1/48

(52) U.S. Cl. 341/113

(57) ABSTRACT

A pseudo-absolute position of a rotating axis is sensed at a desired resolution by employing a single absolute encoders of a resolution that is lower than the desired resolution in combination with a home position sensor that is activated by a home position actuator attached to the axis. The home position sensor and actuator provide an initial count and context of absolute encoder rotations about the axis. Whereas the absolute encoder data is utilized directly for the lower bits of the enhanced position data, overflows and underflows of the absolute encoder data are utilized for the purpose of counting the absolute encoder rotations wherein the rotation count forms the upper bits of the enhanced position data. Additionally, the data from the absolute encoder can be manipulated so as to make a mechanical misalignment between the encoder, the home position sensor and actuator essentially inconsequential to the operation and accuracy of the enhanced incremental-absolute position sensor system.

### CROSS REFERENCE TO RELATED APPLICATIONS

Not Applicable

### FEDERALLY SPONSORED RESEARCH

Not Applicable

### SEQUENCE LISTING FOR PROGRAM

Not Applicable

### BACKGROUND OF THE INVENTION

1. Field of the Invention

The present invention relates to the field of position measurement; and more specifically, the present invention relates to the measurement of an angular position of a rotating shaft.

### BACKGROUND OF THE INVENTION 2. Prior Art

A machine may be created that is then operated by a control system referred herein to as a “Computer”. During operation of this machine, the computer may need to ascertain the position of various mechanical elements, referred singly herein to as an “Axis”. The axis may be moved relative to the other components of the machine and or to some fixed position relative to a location in which the machine is installed. For machines for which the movement is rotational, the position of the axis is generally reported as an angle in degrees from some arbitrary origin where that origin is reasonably expected to be the same from one use of the machine to the next. In the course of the design of the computer and machine, the angular position of the axis may be represented in the standard form in the art of 0 to 360 degrees or as an arbitrary range of values which may then be translated to the standard form or used as is. An example of an arbitrary range would be 0 to 9,999 counts wherein a count would generally be the smallest increment of rotation that can be measured. As is generally accepted and would be familiar to one skilled in the art, the “Resolution” of an axis measurement will interchangeably be referred to as the smallest increment of angle which is represented by one count or as the total number of incremental counts which comprises a full rotation about the axis. By way of example, a resolution of one degree would generally be considered as being interchangeably referred to as a resolution of 360 counts.

The computer that controls the machine may get its axis position data from sensors known as encoders, which may be of the incremental or absolute types for example. Each axis within the machine may utilize encoders of the same type or may combine different types as dictated by the design of the system. Ultimately, whatever type of encoder is employed, these encoders will produce within the computer a grouping of digital bits that represent the position of the sensed axis. These bits may then be interpreted and or acted upon as required by the design of the system.

Incremental encoders count, or emits pulses that represent the finite increments of rotation of the axis to which they are coupled. These pulses generally contain no information about the actual absolute position of the axis but usually will indicate the direction of rotation as is, for example, the situation for an encoder which utilizes a quadrature output as would be familiar to one skilled in the art. Generally, an incremental encoder will be coupled either directly to the axis of rotation or, for example, to the drive motor of a geared-down system in order enhance the resolution of the encoder by means of multiplication of the number of rotations of the encoder versus the rotation of the axis to which it is coupled. It must be noted that this incremental encoder may not always be an actual sensor but may be intrinsic to the operation of the drive system, as is the case when the computer counts commanded incremental steps of movement of a synchronous drive motor, herein referred to as a “Stepper motor”.

In the case of a computer which counts pulses from an external incremental encoder, a loss of position information may ensue should a pulse occur but the computer is not able to detect the pulse. For example, a processing speed limitation of the computer could cause it to miss a pulse within a sequence of pulses because it is busy with an interrupt service. Errors due to missed pulses would be exacerbated should the time between these pulses be reduced, as for an increase in the speed of rotation of the axis, for a system near its operational limit. For a quadrature encoder signal, a missed pulse may further entail a loss of direction information as well, thereby compounding the error. In the case of a computer which counts stepper motor increments, a loss of position information may ensue should a step of movement not occur as commanded, commonly referred to as a “Stall” or when an external force is applied that exceeds the ability of the stepper motor to maintain its expected position, commonly referred to as “Cogging”.

The absolute position will generally be established by the computer at the beginning of operation by moving the axis to a known location herein referred to as the “Home” position. The home position is typically established by means of a sensor whose position is fixed relative to the axis, such as an optical interruption or magnetic sensor, that emits a signal to the computer when ever an actuator that is attached to the axis transits through a “Detection window” of the sensor. When the computer receives the signal, the computer sets the increment count to a pre-determined value that is typically defined as zero. As is commonly the case with the sensors typically applied for the purpose of home position determination, the angular position at which the signal is emitted by the sensor to the computer will generally not be exactly the same from one operation of the machine to the next, i.e. a home position error. This home position error is generally due to variations in the operation of the particular type of sensor employed. For example, an optical interruption sensor that uses an opaque light blocking paddle as the actuator, a light emitter and a light detector may require a slightly different detector illumination to emit the home signal at one temperature of operation versus another temperature, or the apparent optical blocking edge of the paddle may change over time as contamination or corrosion on the paddle surfaces alters its optical properties. For a magnetic sensor, the home error may be due for example to variations in magnetic flux coupling versus temperature, ferrous materials inside or outside the mechanical system, or even the earths magnetic field. A further example of a home positioning error source for any type of sensor used arises from the timing between the movement of the axis and the opto-electrical speed of the sensor and the speed at which the computer may react to the signal from the sensor. By way of example, when the axis is in motion as will be required for the purpose of home position seeking and where an optical sensor is employed as the home sensor, there may exist a finite delay between the arrival of the light blocking paddle to a position which can be sensed by the home position sensor, the activation of the sensor, the transmission of the signal to the computer and finally the interpretation of that signal by a software code in the computer. During this delay the axis may have continued to move causing the computer to be in error as to the actual occurrence of the home sensor activation versus the commanded (Expected) axis position. The axis may be made to move at progressively slower rates to minimize this motion induced error, however static errors intrinsic to the sensor alone as described above may not so easily be ameliorated.

After establishing the home position about the axis, the computer may then count increments of angle in either direction of rotation and thus sense the current axis position, or move the axis to a desired angle represented by a specific number of those increments.

Absolute encoders overcome the home position ambiguity as well as the “loss of position” shortcomings inherent to incremental encoders as they are generally capable of reporting position information for a sensing element coupled to the axis, without the need of a repeated initialization with regards to their position about that axis or even a presence of power. Absolute encoders have been realized in a variety of manners including optical disks with one or more patterns that directly represent the angular position of the pattern, “Synchros” which are rotating transformers with windings with specific phase-to-position relationships that may be translated to a digital form with electronics and magnetic field position sensing encoders. The benefits of an absolute encoder of a given resolution may generally be considered to come at a significant cost premium versus an incremental encoder capable of the same resolution, this added cost most generally stemming from a significant increase in complexity of manufacture for the absolute encoder versus the incremental encoder. Further more, an absolute encoder of “n+1” bits will represent an increase in resolution that is double that of an encoder of “n” bits, so for two absolute encoders of similar design even one more bit of resolution may be found to incur a significant increase in cost. Where a requirement of encoder bits causes the cost of a desirable absolute encoder to exceed the available resources of a particular project, a system designer may be forced to employ a lower cost incremental encoder of equivalent resolution, while forgoing the advantages that an absolute encoder would have afforded. Alternatively, the system designer may select an absolute encoder of lower resolution that desired to retain the benefits of the absolute encoder.

An absolute encoder of greater resolution than permitted by the basic form as described above may be realized in what is known in the art as a “Multi-turn” absolute encoder. A multi-turn absolute encoder typically utilizes the resolution multiplication technique of the geared-down incremental encoder described above. An example of a prior art, multi-turn absolute encoder entails employing an integrated speed-reducing gear that is coupled to a turn counting device. Common limitations of the accuracy of an encoder where a speed-reduction gear is employed include but are not limited to, errors from backlash, mechanical alignment or mechanical wear. Of particular concern to the system designer, these errors would be separate from and typically uncorrelated to, the same mechanical errors within the axis drive train to which the encoder is coupled. A second example of a prior art multi-turn absolute encoder is the magnetic bubble counting type that while not necessarily manifesting the same mechanical error sources of the gear reduction apparatus, introduces its own shortcomings including costs commensurate with the complexities of realization, all of which may not be trivial to the system designer.

### OBJECTS AND ADVANTAGES

Accordingly, the objects and advantages of the present invention are:

(a) to produce an enhanced pseudo-absolute position reading of an angle about an axis of rotation from a combination of an absolute encoder and a home position sensor, where the absolute encoder resolution is multiplied up to the desired enhanced resolution;

(b) to utilize mechanical elements within an existing mechanical system or an ancillary mechanical element for the purpose of resolution multiplication;

(c) to enable a convenient and economical installation of the absolute encoder and home position sensor upon an axis of the existing mechanical system or the ancillary mechanical element with minimal regard to the actual mechanical alignment of the absolute encoder and home position sensor with respect to the axis;

(d) to provide a means by which a mechanical and or temporal misalignment between the encoder and the home position sensor which may result from the installation of the encoder and home position sensor may be reduced or eliminated; and

(e) to eliminate any ambiguity of a detected home position which may arise from one operation of the system to the next.

Still further objects and advantages will become apparent from a consideration of the following description and drawings.

### SUMMARY

A method for an enhanced incremental-absolute position sensor system for producing an enhanced pseudo-absolute position reading of an angle about an axis of rotation having a number of rotation count bits and a number of rotation position bits is disclosed. In an exemplary embodiment of the present invention, a home position actuator is positioned upon an axis so as to be able to pass through a detection window of a home position sensor attached to a fixed position with respect to the axis. An absolute encoder is coupled so as to rotate an integer multiple number of times greater than one for each full rotation of the axis. A computer is connected to the home position sensor and the absolute encoder by a means such that signals may be received from the home position sensor and position data may be read from the absolute encoder. A computational means is provided whereby the mechanical misalignment of the home position sensor and the absolute encoder is minimized to an extent possible, thereby eliminating any ambiguity arising from operational variability of the home position sensor. A further computational means is provided whereby the multiple rotations of the absolute encoder with respect to the single rotation of the axis may be counted. The enhanced pseudo-absolute position reading may then be utilized by an external system or as an integral part of a local system.

### DRAWINGS

### Figures

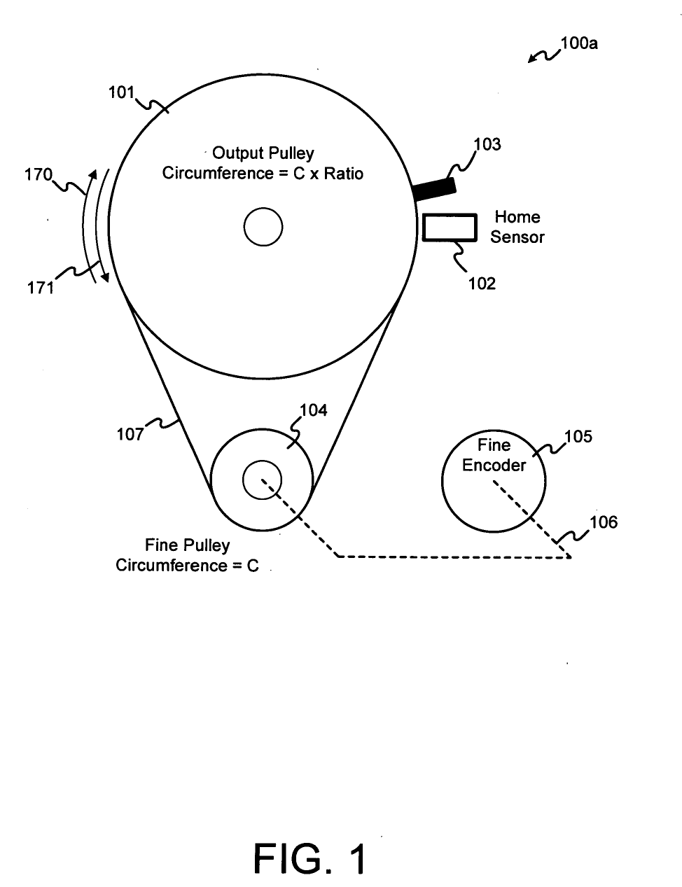

FIG. 1 illustrates an exemplary arrangement of a home position actuator, home position sensor, fine encoder, encoder coupling, pulleys and a power transmission belt wherein the fine encoder lies within the drive chain in one embodiment of the present invention.

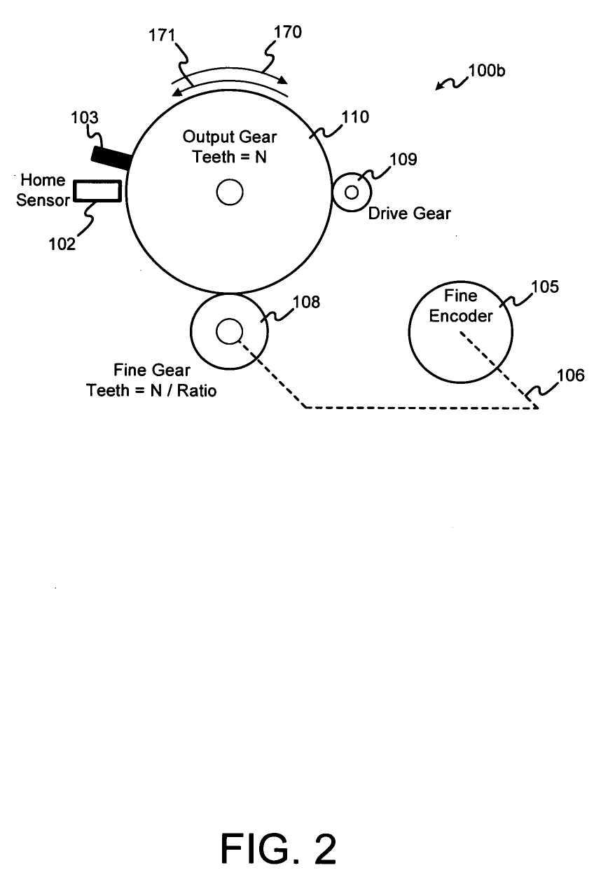

FIG. 2 illustrates an alternative exemplary arrangement of a home position actuator, home position sensor, fine encoder, encoder coupling and gears wherein the fine encoder lies outside the drive chain.

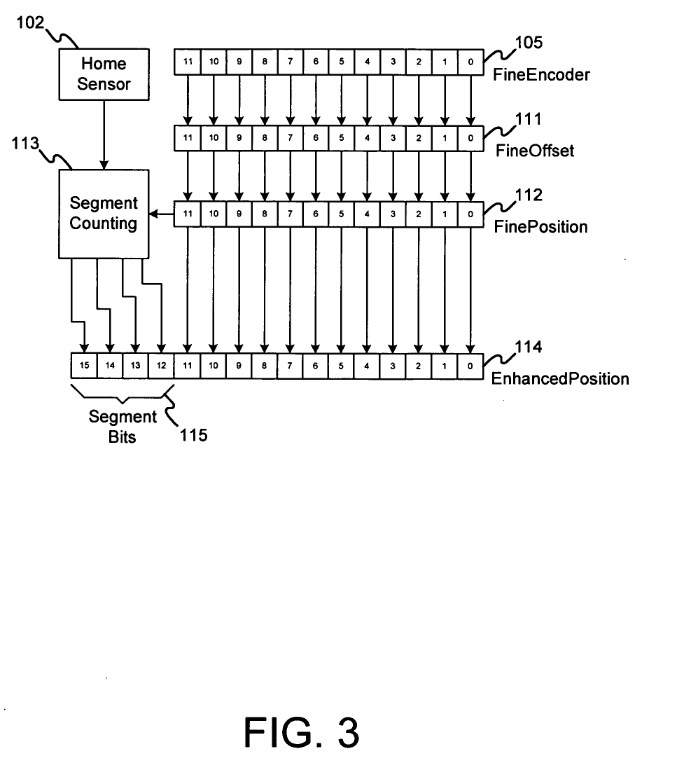

FIG. 3 illustrates the relationship between the bit positions of the fine encoder, fine alignment offsets, alignment corrected fine position data, a segment counting block which produces a group of segment bits and a resultant enhanced pseudo-absolute position.

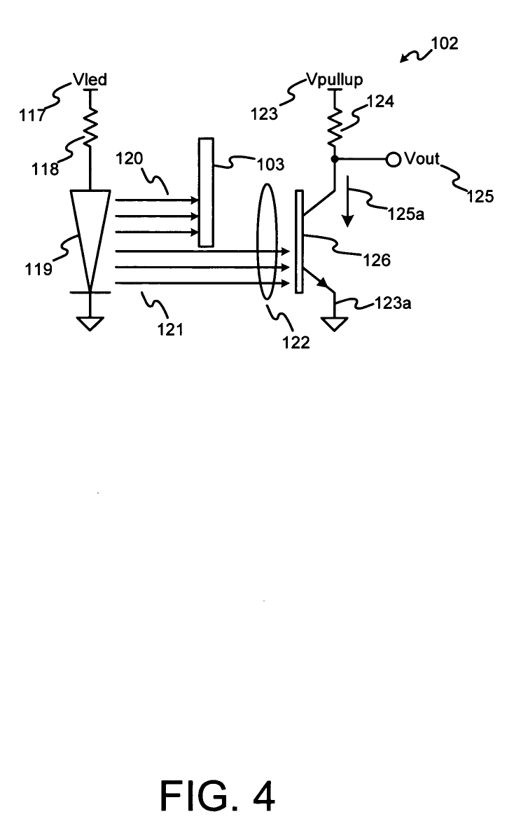

FIG. 4 illustrates a typical optical home position actuator and sensor arrangement utilizing sensor illumination blocking.

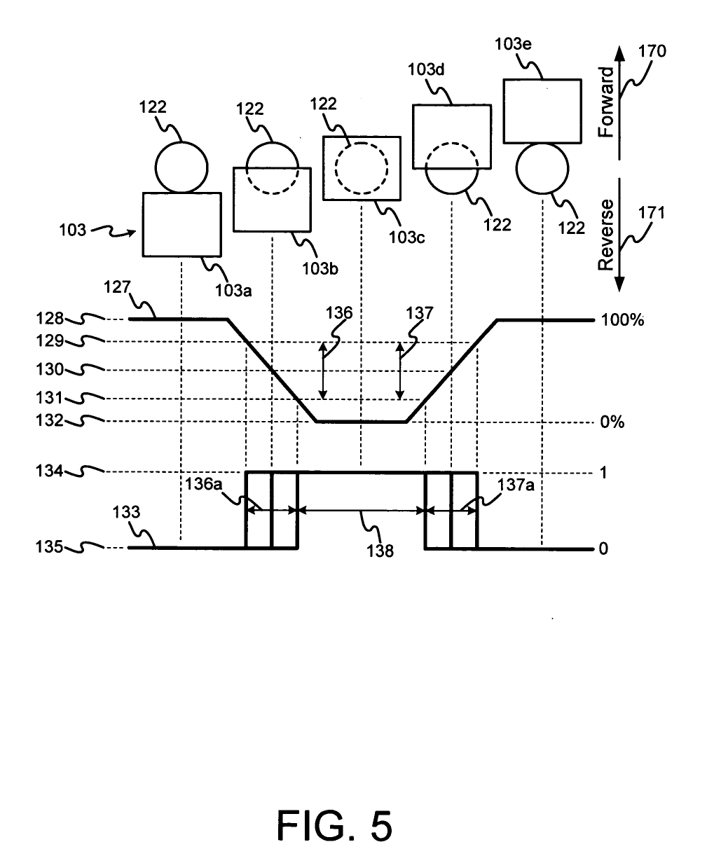

FIG. 5 illustrates the relationship between the home position actuator, home position sensor illumination and the home position sensor logical output signal.

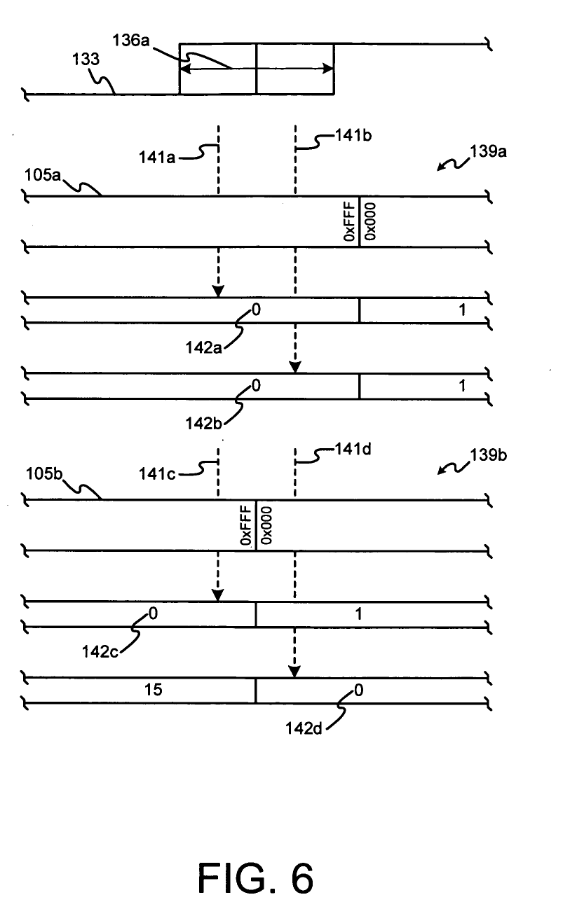

FIG. 6 illustrates the relationship between a misaligned and an aligned fine encoder data with respect to the home sensor ambiguity and the resulting segment decisions made by the computer.

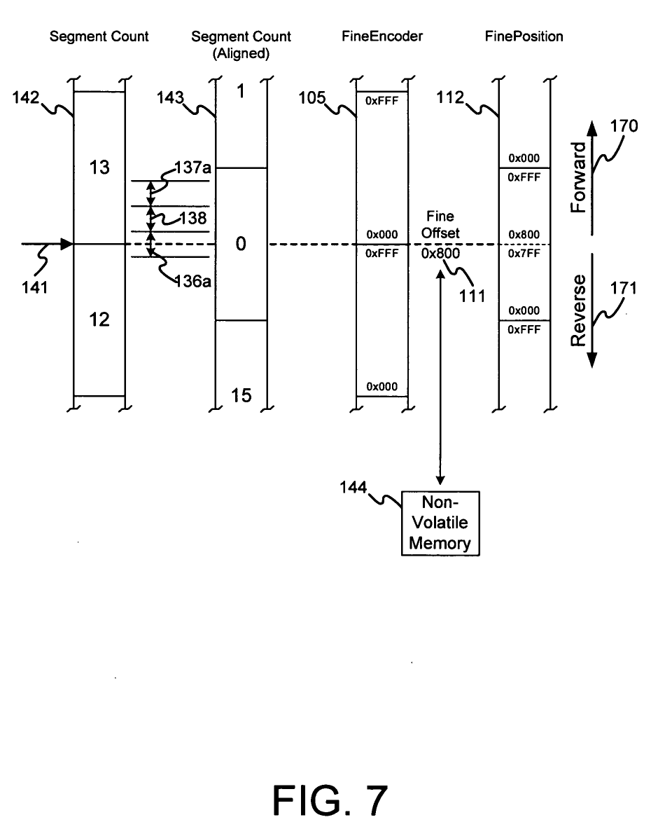

FIG. 7 illustrates the relationship between the unaligned and aligned segment counts, the unaligned fine encoder data and the fine position data for an arbitrarily chosen axis alignment decision point, and the resulting alignment offset and offset non-volatile memory storage.

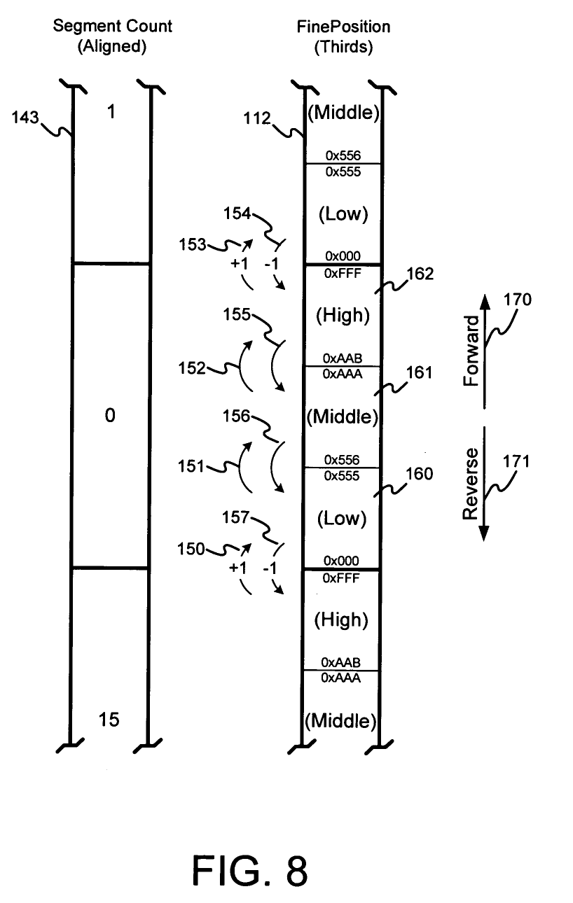

FIG. 8 illustrates the relationship between the aligned segment count and the transitions between the fine position “Thirds”.

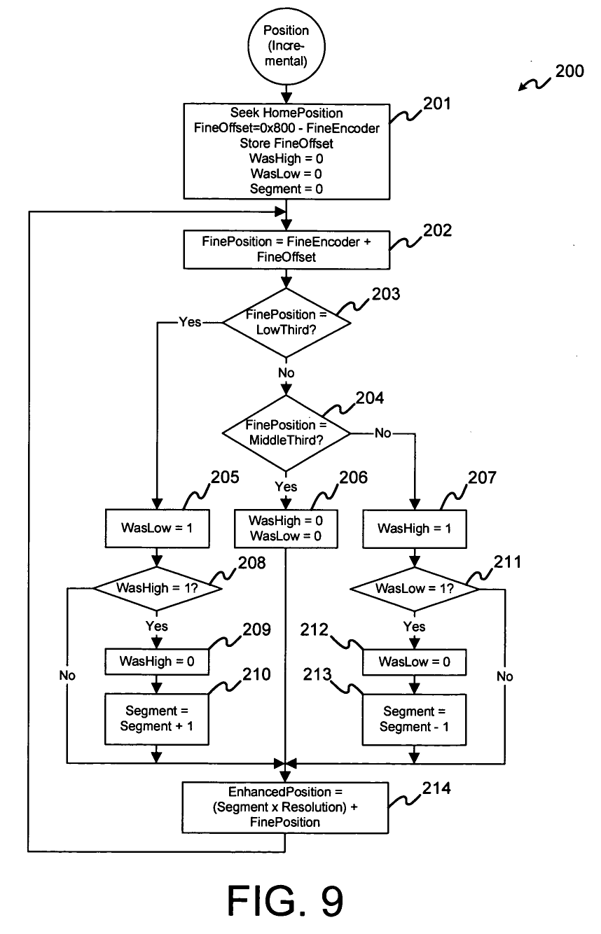

FIG. 9 illustrates an exemplary flowchart of a software program used to numerically align the fine encoder data, adjust the segment count up and down due to fine position data changes and then repeatedly compute an enhanced resolution pseudo-absolute position from the segment count and fine position data.

### DETAILED DESCRIPTION

### FIG. 1—Preferred Embodiment

Referring first to FIG. 1, there is shown an exemplary arrangement of mechanical, sensor and encoder elements in accordance with one embodiment of the present invention. As discussed below, a home position sensor 102 and a fine encoder 105, when coupled into such an appropriate mechanical system and processed with an appropriate algorithm will yield pseudo-absolute angular position data of an axis with a resolution that is greater than fine encoder 105 is alone capable of, while eliminating ambiguity associated with an operational variability of the home position sensor 102.

By way of illustration, the encoder system 100a is suitable to convert the angular position of an axis in a mechanical device such as a camera pointing system such that the camera may be pointed repeatedly at some target location in the environment into which it is installed. A typical system would include, among other things, motors to provide forces with which to effect movement of the camera in either direction about one or more axis, belts, pulleys or similar elements to transfer those forces, and electronic devices such as computers within and without the mechanical device which are capable of controlling said motors in addition to interpretation, computation and storing of information related to the positions to which the device will be commanded to move. As such, encoder system 100a may be integrated into the camera control system for example to provide positional data and allow accurate, repeated pointing of the attached camera.

Although not shown for ease of illustration in FIG. 1, a motor will typically be coupled to a fine pulley 104, that may also be called a “Drive” pulley, which is then connected to motor control electronics and ultimately to a system control computer. The actual mechanical elements and configuration chosen to transfer the force from the motor to the axis may also be sprockets with chains and gears for example, or any combination of these devices as dictated by the mechanical design requirements. The limitations placed on the mechanical and computer systems as dictated by the encoder system will be detailed below. Home position sensor 102 and fine encoder 105 may be connected to the machines control system or to some other computer, to which data may be read from the sensor and encoder and then processed according to the present invention by a means familiar to those experienced in the art. The computer enlisted to implement the requirements of the present invention will have whatever inputs and outputs, memory both volatile and non-volatile and other elements as required for this and all other functions it is expected to perform.

As depicted in FIG. 1 and for one embodiment for the present invention, an output pulley 101 which rotates about an axis that is to have its angular position measured is coupled by a drive belt 107 to the fine pulley 104. A home position actuator 103 is attached to the output pulley 101 such that it may transit though a detection window of the home position sensor 102 that is attached to some fixed position with respect to the axis. A fine encoder 105 is coupled via a coupler 106 to the fine pulley 104. Coupler 106 may be of various mechanical, optical, magnetic or other types as required by the particular model of fine encoder employed. The fine encoder 105 must be capable of reporting absolute angular position with the requirement for the number of bits of resolution for the fine encoder 105 being discussed in detail below.

For the exemplary embodiment of the present invention, the convention used herein will be that the direction of rotation of the output pulley 101, alternatively referred to as the “Axis”, in the forward direction 170 as reported by the fine encoder 105 will be indicated as an increase in counts whereas a movement of the axis in the reverse direction 171 as reported by the fine encoder 105 will be indicated as a decrease in counts. The specific manipulation of the reported position information from the encoder for the purpose of implementation in this or any other embodiment of this invention, such as inversion of a reading to cause the count to appear to increase for forward rotation of the axis, is familiar to those skilled in the art and so will not be further covered herein.

The exemplary embodiment of the present invention requires that the ratio, or alternatively “Gear ratio”, between the output pulley 101 and the drive pulley 104 be an integer multiple greater than one such as 2:1 or 3:1 where the resulting enhanced resolution of the entire encoder system will be that ratio multiplied by the resolution of the fine encoder 105. By way of example, a mechanical gear ratio of 4:1 paired with a fine encoder 105 of 4096 counts of resolution will yield an enhanced position resolution of 16,384 counts per full rotation of the coarse pulley 101. For the exemplary embodiment of the present invention the gear ratio will be understood to be 16:1 and the resolution of the fine encoder will be 4,096 counts, resulting in an enhanced pseudo-absolute position resolution of 65,536 counts.

In the exemplary embodiment of the invention shown in FIG. 1, the force transmitted by the drive pulley 104 to the output pulley 101 through the drive belt 107 could result in a strain on the belt further resulting in a backlash error; i.e. the drive pulley 104 must rotate some finite angle before that rotation is transmitted to the output pulley 101, this effect inducing an axis position measurement error in the encoder system 100a. Backlash and the resultant error is not particular to the present invention so will not be covered herein in detail, however for completeness and to introduce additional benefits of the present invention, the proceeding paragraph for the present embodiment and the description of an alternate embodiment as shown in FIG. 2 shall be included.

An example of a method to compensate for backlash induced errors such as described in the preceding paragraph could include for example, but not be limited to, selecting a drive belt 107 that is more rigid or may contain teeth as is the case for a “Gear belt”, therefore transmitting power from the drive pulley 104 to output pulley 101 more effectively.

### DETAILED DESCRIPTION

### FIGS. 1, 3, 4, 5, 6,7 and 8—Operation

FIG. 3 depicts the data flow within an exemplary embodiment of the invention wherein a home position sensor 102 and a twelve bit fine encoder 105 are employed to produce an enhanced position 114 of sixteen bits.

A fine offset 111 is computed and stored as discussed in detail for FIG. 6 below. The fine offset 111 is added to the current and subsequent readings of fine encoder 105 to produce an offset corrected or “Aligned” fine position 112 that is mapped directly into the twelve low order bits of the enhanced position 114.

For the proceeding discussion, the upper four bits of the enhanced position 114 will be herein referred to collectively as the “Segment bits” 115. Each of the possible values of the segment bits 115 represent the angle of rotation of the coarse pulley 101 of FIG. 1 for which the fine pulley 104 of FIG. 1 has made a full rotation, wherein the value represented by the segment bits 115 will vary between zero and the previously described gear ratio minus one for a full rotation of the axis. Segment counting block 113 examines the fine position data 112 periodically and by a process described below will count rotations both forward and reverse of the fine encoder 105. The result from the segment counting block 113 is then mapped into the segment bits 115 producing the full sixteen bit enhanced position 114 result.

As previously indicated, the maximum value of the segment bits 115 is determined by the gear ratio of the fine pulley 104 to the coarse pulley 101 minus one. For the exemplary embodiment of the current invention, the gear ratio is sixteen and so therefore the maximum value of the segment bits 115 will be fifteen. Four bits are required to represent fifteen in binary and so therefore four segment bits 115 are required.

Referring to FIG. 4, an exemplary home position sensor 102 and home position actuator 103 are illustrated and described. A typical optical interruption type of home position sensor 102 will consist of a light emitting diode 119 powered from a voltage source Vled 117 that is current limited by a resistor 118. A group of light rays 120 and 121 are emitted from the light emitting diode 119 in the direction of a light detecting transistor 126 forming a light detection window 122. When the home position actuator 103 passes between the light emitting diode 119 and light detecting transistor 126 such that it covers a portion of the light detection window 122, light rays 120 are blocked while light rays 121 are permitted to pass and thereby fall upon the surface of the light detecting transistor 126: A current 125a flows through the light detecting transistor 126 that is roughly proportional to the permitted light rays 121, or illumination, striking its surface, this current 125a causing a voltage “Vout” 125 to develop across the pull up resistor 124, that with respect to a ground 123a is inversely proportional to the illumination striking the surface of light detecting transistor 126 and that may vary from between Vpullup 123 and ground 123a.

Variability in the operation of home position sensor 102 with respect to the position of the home position actuator 103 within the light detection window 122 may include but not be limited to, variations in the voltage of Vled 117, the resistance of the resistor 118, the light emitting characteristics of the light emitting diode 119 and the illumination to current function of the light detecting transistor 126. The primary effect of all possible variations elements within the home position sensor 102, when taken together, is to cause multiple positions of the home position actuator 103 to be represented by a single Vout 125, i.e. a “home position ambiguity” as described below.

Referring to FIG. 5, relationships between the position of the home position actuator 103 with respect to the light detection window 122 and a resulting sensor logic signal 133 are illustrated. For the purpose of establishing a known position of the axis, the axis is rotated such that the home position actuator 103 is made to approach the home position sensor 102. During a rotation of the axis in the forward 170 direction the home position actuator will be made to transit through the fixed light detection window 122 as illustrated by the five positions 103a-to-103e of the home position actuator 103. A relative illumination curve 127 of light rays striking the surface of the light detecting transistor produce the inversely proportional Vout that is then interpreted by electronics within the computer as the sensor logic signal 133. An Illumination level 128 represents the maximum, and an illumination level 132 represents the minimum available illumination onto the light detecting transistor through the light detection window 122 that is either completely unblocked or fully blocked respectively. A completely unblocked illumination level 128 corresponds to a sensor logic signal 133 of a logical “Zero” 135. A fully blocked illumination level 132 corresponds to a sensor logic signal 133 of a logical “One” 134.

The home position ambiguity arises from a situation typical in an actual system where the home position actuator 103 is not limited to positions that either completely unblocked or, fully block the light detection window 122. In general, the home position actuator must generally pass through a “Linear” region represented by a home position actuator position 103b that results in a range of illumination 136 represented by illumination levels 129, 130 and 131. In the worst case, sensor variability, the zero-to-one threshold of an input logic circuit employed by the computer for the purpose of reading the home sensor 102 result in a realistic range of logical state transition 136a, and therefore a range of rotational angles that may be interpreted as the “True” home position. Generally speaking, most sensors including magnetic switches (Reed), magnetic flux detection (Hall) and mechanical switches that are commonly employed for the purpose of establishing a home position will exhibit the same errors as described for the exemplary optical interruption sensor.

The above discussion applies equally when the home position sensor 102 is approached by the home position actuator 103 from the reverse 171 direction with a range of illumination 137 being roughly equivalent to the range of illumination 136 and a range of logical state transition 137a being roughly equivalent to the range of logical state transition 136a. A home position sensor off state 138 is as wide as the angular width of the home position actuator 103 in terms of the angle of rotation of the axis. The implications of the direction of the home position seeking operation as discussed above with respect to angular widths of the ranges 136a, 138 and 137a will be covered in more detail below.

When applied as detailed below, the essential benefits of the combination of the absolute nature of the fine encoder and the proceeding alignment procedure is to eliminate the home position ambiguity introduced by the typical home position sensor, thereby rendering an uncertain rotational alignment of the fine encoder to the axis (and therefore the home position sensor) essentially irrelevant while enabling the resolution multiplication of a purely incremental encoding solution without the computer processing overhead or hard logic that a purely incremental solution would typically require.

Referring to FIG. 6, once assembled into the mechanical system and as dictated by the nature of operation of the fine encoder, the system does not require a strict establishment of the absolute angular position of the home position actuator relative to the fine encoder. However, because the fine encoder does rotate a multiple number of times, each rotation represented by a full count of the encoder of 0x000 to 0xFFF, for each full rotation of the axis for the purpose of resolution multiplication the computer must at the very least establish the correct rotation count of the fine encoder relative to the axis. The home position ambiguity as regards the rotation count can be illustrated as detailed below. Suppose the segment counting block were programmed as detailed below to set the rotation or “Segment” count to zero when, during a home position seeking event, the signal form the home position sensor is received by the computer. As illustrated by alignment diagram 139a, if the range of logical state transition 136a of sensor signal 133 was positioned outside the 0xFFF-to-0x000 count boundary of a fine encoder 105a reading, the segment counts 142a and 142b of zero would be established for both home position seeking decision points 141a and 141b respectively. For both extremes of the range of logical state transition 136a there would be no ambiguity for a randomly “Aligned” fine encoder in this case. If however, as illustrated by alignment diagram 139b, the range of logical state transition 136a was positioned across the 0xFFF-to-0x000 count boundary of a fine encoder 105b reading, the segment count 142c of zero would be established at one extreme of the range of logical state transition 136a at decision point 141c and the same segment count 142d of zero would be established for fine encoder 105b at the other extreme of the range of logical state transition 136a at decision point 141d. These two segment counts of zero would unfortunately be for completely different actual rotations of the fine encoder as represented by the fine encoder 105b reading, i.e. an ambiguity of one rotation for a randomly “Misaligned” fine encoder. To eliminate the home position ambiguity, the apparent 0xFFF-to-0x000 boundary of the fine encoder data must be shifted away from the home position sensor state change. The procedure for shifting the apparent boundary is described below.

The underlying binary mathematics commonly used in computers as referenced in the proceeding sections that involve addition, subtraction, division and other operations for fixed numbers of bits are familiar to those skilled in the art so will not be covered here in detail. All operations will be unsigned integer operations.

In the exemplary embodiment of the present invention, as illustrated in FIG. 7 and for which it would be desirable for simplification of manufacture, when the home position sensor, home position actuator and the fine encoder are assembled into the mechanical system a random rotational alignment between a home position sensor detection signal and the fine encoder data will likely be observed. The present invention provides a computational means to compensate for this misalignment thus removing ambiguity of the segment count from one home position seeking operation to the next.

Referring to FIG. 7, in order that an initial home position is established for a first operation of the machine, the axis is rotated such that the home position actuator is made to activate the home position sensor, which signal is sensed by the computer thereby establishing an alignment decision point 141, shown as entails a worst case misalignment as described previously with a random segment count 142. As described above, the segment count is set to zero by the segment counting block establishing a home segment count 143 of zero. The computer further computes a fine offset 111 by subtracting the current fine encoder 105 reading from one half the maximum value of the fine encoder, this being 0x800 in the exemplary embodiment of the present invention. The fine offset 111, 0x800−0x000=0x800, is then stored by the computer for later retrieval in a non-volatile memory location 144. The fine offset 111 is added to this and all subsequent fine encoder 105 readings yielding the fine position 112 data. The segment counting described graphically in FIG. 8 and programmatically in FIG. 9 will be applied to the fine position 112 data. The result of the above operation is to computationally “Push” the count transitions of the fine position data as far away from the home position sensor actuation as is possible. By this alignment adjustment, a system can achieve nearly an optimal situation of “Alignment” as described for diagram 139a wherein no ambiguity of current segment count is encountered.

Because the speed of the rotation of the axis as described for the operation of the home position sensor can represent an increase in the width of the range of logical state transition 136a, the slowest possible rate of rotation of the axis would be desirable for the initial home position seeking operation. If subsequent home position seeking operations are to performed from either of the directions forward 170 or reverse 171, the actual width of the home position sensor activation signal ambiguity would be increased to encompass the total of the width of logical state transition 136a, the width of home position sensor off state 138 and the width of logical state transition 137a. For this reason it would be desirable in some instances for all home position seeking operations to be performed in the same direction of rotation although this choice would ultimately depend on the angular width of the combination of ranges 136a, 138 and 137a with respect to the angular width of a single rotation of the fine encoder, i.e. the home position sensor activation signal must not cross a 0xFFF-to-0x000 boundary of the fine position 112 data.

Once the fine offset 111 has been computed an stored, should the computer for example have lost power and thereby lost its current count of fine encoder rotations 143 relative to the axis, upon re-starting, the computer must perform the following sequence of events. The fine offset 111 is retrieved from the non-volatile memory 144 that is then applied to all subsequent fine encoder 105 readings to produce the fine position 112. If the home position sensor is already in the activated state, the axis should be rotated until the home position sensor is in the deactivated state for the reason described above pertaining to ranges 136a, 138 and 137a. The axis is rotated, preferably in the same direction as was used for the first home position seeking operation, until the home position sensor is activated at which time the segment count 143 is set to zero. The operation of the system may then proceed normally. The speed of the axis during these subsequent home position seeking operations may be as fast as desired such that the first fine position 112 data read for the purpose of segment counting described below for FIG. 8 after the segment count has been set to zero, must occur within the current segment; this of course now being zero. The “On the fly” initialization capability of the present invention is in stark contrast to the generally accepted method of home position initialization as used in a purely incremental encoder system, i.e. every reestablishment of the home position is done as slowly as possible to minimized sensor ambiguity alternatively call “Sneaking up on the home sensor”.

Referring to FIG. 8, a current segment 143 is computed within the segment counting block by essentially counting the overflows in the forward 170 direction or underflows in the reverse 171 direction of the fine position 112 data. By dividing the available counts of the fine position 112 data into three sections, the low third 160, middle third 161 and high third 162, a simple logic may be applied to detect transitions from one third to the next that also maximizes the allowable time that may elapse between subsequent fine position 112 readings. Note that even though in the exemplary embodiment the resolution range of 0 to 4095 counts divides evenly into thirds, even division is not an actual requirement of this invention. For example, with an encoder resolution of 126 counts, “thirds” of 42, 42 and 43 would be appropriate.

As is familiar to those experienced in the art, logical “Flags” are utilized to retain information about previous states for the purpose of programmatic decisions, and in this case a “Low flag” is used to indicate when the fine position 112 data Was (“Set”) or Was-not (“Cleared”) previously in the low third 160 and another “High flag” is used to indicate when the fine position 112 data Was (“Set”) or Was-not (“Cleared”) previously in the high third 162. No specific flags are required for the fine position 112 data in the middle third 161, this condition indicated by both the low and high flags being clear at the same time.

Three computational rules are established for the purpose of counting rotations of the fine position 112 data: (1) A reading of fine position 112 within the middle third 161 clears both the low flag and high flag; (2) a reading of fine position 112 within the low third 160 sets the low flag and if the high flag was set increments the segment count by one and then clears the high flag; and (3) a reading of fine position 112 within the high third 162 sets the high flag and if the low flag was set decrements the segment count by one and then clears the low flag.

By way of example, a rotation of the axis in the forward 170 direction, starting at a home position segment of zero, i.e. at the center of the middle third 161, both the low flag and high flag are cleared by application of rule 1 above. As the axis is rotated, the fine position 112 count will increase, eventually crossing the middle third 161 and high third 162 boundary 152. Application of rule 3 above sets the high flag but performs no counting. Further rotation of the axis will increase the count of fine position 112 such that it will cross the boundary 153 and that, by application of rule 2 above sets the low flag, increments the segment count and clears the high flag. Should the axis immediately move in the reverse 171 direction such that the fine position 112 data crosses the 154 boundary (which is the same as the boundary 153 but in the opposite direction), application of rule 3 above will set the high flag, decrement the segment count and then clear the low flag. Should the axis rotate across the boundary 153 and then back across the boundary 154 before the fine position 112 has been read, no new flags will have been set and so no counting will occur, this being useful should the fine position 112 data “Jitter” at a rotation boundary faster that the computer can read the fine encoder. Similarly, by application of the above three rules, all boundary 150-to-153 crossings in the forward direction 170 and all boundary 154-to-157 crossings in the reverse 171 direction may be accounted for as further programmatically detailed for FIG. 9.

For one skilled in the art, from the discussion above it may be seen that the only requirement for the accurate counting of the multiple fine position 112 (and therefore fine encoder) rotations for each single rotation of the axis is that at least one reading of the fine position 112 data must be performed within a low third 160, middle third 161 or high third 162 for each transit through that third.

By way of example, an exemplary system as shown in FIG. 1 with an encoder of the resolution as depicted in FIG. 3 and designed for a maximum desired axis rotation of 180 degrees per second, one fine position 112 third will be equal to 360 degrees divided by sixteen segments divided by three thirds per segment or 7.5 degrees per third. 7.5 degrees per third divided by 180 degrees per second indicates no more than 41.67 milliseconds may elapse between consecutive fine position 112 readings if the counting of segments is to be successful.

By way of further example, an exemplary system as shown in FIG. 1 with an encoder of the resolution as depicted in FIG. 3 wherein a predefined limitation of the computer exists such that a maximum of 200 microseconds will elapse between fine position 112 readings, one fine position third will be 360 degrees divided by sixteen segments divided by three thirds per segment or 7.5 degrees per third as was the case for the previous example. For 7.5 degrees per third divided by 200 microseconds between readings of consecutive thirds, 37,500 degrees per second is indicated as the maximum allowable rotational speed of the axis if the counting of segments is to be successful.

Referring to FIG. 8, flow chart 200 illustrates an exemplary algorithm to implement the method for the present invention. A first home seeking and alignment cycle 201 is performed whereby a fine offset is computed at the home sensor detection point from the fine encoder reading and stored for later use and the segment count and flags are cleared. Subsequent initializations will restore the fine offset instead of compute and store it, all other operations in 201 remaining the same.

In 202 a fine encoder position is read and adjusted with fine offset to produce the fine position. In 203, if the fine position is in the low third, then the low third is flagged in 205. If the high third was flagged as determined by 208, the high flag is cleared in 209 and the segment count is incremented in 210, else nothing is done. The enhanced position is computed in 214 wherein the segment count forms the upper bits and the offset adjusted fine position forms the lower bits of the enhanced position. The process repeats indefinitely at 202 for each subsequent computation of the enhanced position wherein readings of the fine position that lie within the middle third follow the path of 202, 203, 204, 206 and 214 and readings of the fine position that lie within the high third follow the path of 202, 203, 204, 207, 211, 212, 213 and 214.

### FIG. 2—Additional Embodiment

Another means to alleviate backlash could be realized as depicted in a second exemplary embodiment of the present invention as shown in FIG. 2 wherein encoder system 100b illustrates an alternative, but not necessarily the only other configuration of the elements required to realize the present invention. The embodiment of the invention shown in FIG. 2 consists of a home position actuator 103 coupled to an output gear 110 and fine encoder 105 coupled to fine gear 108 by way of fine coupler 106 as required by the model fine encoder employed. The arrangement of the fine encoder 105 such that it is coupled to fine gear 108 that lies outside of the drive chain consisting of drive gear 109 and output gear 110 whereby that drive force is not transmitted through the gear to which the encoder is coupled may reduce the drive force induced backlash errors. Additionally, the fine gear 108 may be selected to be an anti-backlash type, which may further reduce backlash-induced errors as may be desirable in the system design. Additionally, multiple stages of gear reduction may be placed between the output gear 110 and fine gear 108 as dictated by the availability of these gears.

Per the detailed discussion above for encoder system 100a and as applies to encoder system 100b, the gear ratio of the output gear 110 to the fine gear 108, when multiplied by the resolution of the fine encoder 105 determines the resolution of the entire encoder system. In accordance with the previously stated convention for the encoder system 100a, movement of the axis for the alternative embodiment 100b of the encoder system in the forward direction 170 as reported by the fine encoder 105 will be indicated as an increase in counts whereas a movement of the axis in the reverse direction 171 as reported by the fine encoder 105 will be indicated as a decrease in counts.

### ADVANTAGES

From the description above, a number of advantages of the present enhanced incremental-absolute position sensor system method becomes evident: Off the shelf absolute encoders of lower resolution and therefore significantly lower cost than a single absolute encoder of an equivalent desired resolution may be employed to produce an enhanced pseudo-absolute position reading. A fast and simple, component variability tolerant angular alignment procedure that will not exhibit the home position ambiguity common to purely incremental encoder systems may be utilized. In a typical purely incremental encoder system, every single increment of movement of the encoder and therefore every pulse from the encoder must be processed by the controlling computer or by dedicated logic whereas the present invention requires only a fractional attention to the pulses, thus minimizing the processing speed required to maintain an accurate sense of position. Mechanisms generally already present, or simple dedicated mechanisms, in a typical mechanical system may be utilized for the mechanical multiplication of the output axis rotations instead of dedicated, intricate or precision mechanisms. When the encoder system uses existing mechanisms, errors due to backlash or other similar sources are not then compounded by additional, uncorrelated errors, as are typically introduced by a stand-alone multi-turn absolute encoder. When a dedicated rotation multiplication mechanism is employed, the system designer may specifically control the possible error sources as best serves the system. The method described above reduces or eliminates a need for precise alignment of the multiple absolute encoders and whatever misalignment has been introduced in the construction of the encoder system may then be mathematically reduced or eliminated such that little or no uncertainty is introduced that may lead to errors in the enhanced position data.

What is claimed:

1. A method for computing an enhanced pseudo-absolute position reading for a sensed axis comprising:
(a) providing a home position actuator that is coupled to the sensed axis so as to rotate in concert with the sensed axis;
(b) providing a home position sensor that has a position that is fixed with respect to, the sensed axis that may further be expected to sense the proximity of the home position actuator;
(c) providing an absolute encoder of a desired resolution that is coupled to the sensed axis so as to rotate an integer number of times greater than one for each single rotation of the sensed axis;
(d) providing a means by which the axis may be made to rotate;
(e) providing a means by which data may be read from the home position sensor and the absolute encoder;
(f) providing a non-volatile memory that is able to store a plurality of data;
(g) providing a general-purpose memory that is able to store a plurality of data;
(h) providing a general-purpose computer for the purpose of the reading and manipulation of data from the home position sensor and the absolute encoder, storage of data in the general-purpose and non-volatile memory, selecting from a plurality of logical states for the purpose of computing the enhanced absolute position reading and for the transmission of the enhanced absolute position reading which will;
(1) perform a first home position alignment operation comprising;
(a) reading a home position sensor activation signal temporally correlated to a reading of a fine alignment data from the absolute encoder while the axis is not in motion or in motion at a minimal speed;
(b) subtracting the fine alignment data from a value equal to one half the desired resolution of the absolute encoder to produce a fine offset;
(c) storing the fine offset into a non-volatile memory location;
(d) initializing a segment count to zero;
(e) initializing a low flag memory location to zero;
(f) initializing a high flag memory location to zero; or
(2) perform a subsequent home position alignment operation comprising;
(a) reading a home position sensor activation signal while the axis is not in motion or in motion at a nominal speed;
(b) initializing a segment count to zero;
(c) initializing a low flag memory location to zero;
(d) initializing a high flag memory location to zero; or
(e) retrieving a fine offset previously stored in a non-volatile memory location from the non-volatile memory location;
(3) read a fine position data from the absolute encoder at which time the axis may be stationary or in motion;
(4) add the fine offset to the fine position data to produce an aligned fine position;
(5) select from a plurality of logical functions, the selection of which is made based on the value of the aligned fine position and which is then applied to the segment count to produce a current segment result;
(6) concatenate the current segment result to the aligned fine position whereby the current segment result forms the most significant bits and the aligned fine position forms the least significant bits of the enhanced pseudo-absolute position reading;
(7) transmit the enhanced absolute position reading for subsequent use by the general-purpose computer or an other computer; and
(8) repeat steps (1) whenever the first home position alignment is required as when the first home position alignment has not yet occurred or when the home position actuator, home position sensor or fine encoder have been mechanically reposition with respect to each other; or
(9) repeat steps (2) through (7) whenever the first home position alignment has already been performed and the subsequent home position alignment is required whereby the fine offset may first be retrieved from the non-volatile memory in lieu of performing step (1) as when the current segment count has been lost; or
(10) repeat steps (3) through (7) within a time period such that these steps occur at least once within each consecutive third of the resolution of the fine position data while the axis is in motion;
whereby the enhanced pseudo-absolute position reading of the axis as reported by the absolute encoders and processed by the general-purpose computer will not be degraded by ambiguity due to any operational variation of the home position actuator or the home position sensor with respect to the absolute encoder or by reasonable temporal displacement between subsequent readings of the absolute encoder.
